(19) United States
(12) Patent Application Publication
(10) Pub. No.: US 2019/0182955 A1
(43) Pub. Date: Jun. 13, 2019

(54) REPLACEABLE ON-PACKAGE MEMORY DEVICES

(71) Applicant: Intel Corporation, Santa Clara, CA (US)

(72) Inventors: Gregorio R. Murtagian, Phoenix, AZ (US); Kuang C. Liu, Queen Creek, AZ (US); Sriram Srinivasan, Chandler, AZ (US); Jeffory L. Smalley, East Olympia, WA (US); Zhichao Zhang, Chandler, AZ (US)

(73) Assignee: Intel Corporation, Santa Clara, CA (US)

(21) Appl. No.: 15/841,246

(22) Filed: Dec. 13, 2017

(51) Int. Cl. H05K 1/14; H01R 12/73; H05K 1/11; H05K 1/18; H05K 1/02; H05K 3/36; H05K 3/34

(52) U.S. Cl. CPC H05K 1/145; H05K 2201/09027; H05K 1/117; H05K 1/181; H05K 1/144; H05K 1/0203; H05K 1/141; H05K 3/366; H05K 3/3436; H05K 2201/10159; H05K 2201/10378; H05K 2201/066; H05K 2201/049; H05K 2201/10325; H01R 12/737

(57) ABSTRACT

Electronic device package technology is disclosed. An electronic device package in accordance with the present disclosure can include a package substrate. The electronic device package can also include a processor mounted on the package substrate. Additionally, the electronic device package can include a memory socket mounted on the package substrate and operably coupled to the processor. The memory socket can be operable to removably couple with a memory module and facilitate electrical communication between the processor and the memory module. A memory module can include a plurality of printed circuit boards (PCBs). Each PCB can have a bottom edge and a plurality of contact pads located about the bottom edge. Additionally, the memory module can include a memory device mounted on at least one of the plurality of PCBs and electrically connected to at least one of the pluralities of contact pads to facilitate electrically coupling the memory module with an external electronic component, such as a processor. Associated systems and methods are also disclosed.

### TECHNICAL FIELD

Embodiments described herein relate generally to electronic device packages, and more particularly to electronic device packages with removable electronic components.

### BACKGROUND

Current electronic device package technology often combines several types of electronic devices in a single package. For example, a typical server package includes a processor and memory. On-package memory, however, is not replaceable by an end user, being mounted to package substrates by “permanent” couplings such as surface mounting with solder bumps/balls or wire bonds. To provide flexibility in system memory capabilities, some server packages rely on replaceable memory that is located off-package on the server motherboard. Such replaceable memory is located off-package due to space constraints on the server package substrate.

### BRIEF DESCRIPTION OF THE DRAWINGS

Invention features and advantages will be apparent from the detailed description which follows, taken in conjunction with the accompanying drawings, which together illustrate, by way of example, various invention embodiments; and, wherein:

FIG. 1A is a perspective view of an electronic device package in accordance with an example embodiment;

FIG. 1B is a top view of the electronic device package of FIG. 1A;

FIG. 1C is an end view of the electronic device package of FIG. 1A;

FIG. 2 is a schematic end view cross-section of an electronic component module and an interconnect socket in accordance with an example embodiment;

FIG. 3 is a side view of the electronic component module of FIG. 2.

FIGS. 4A-4K are end views of electronic component modules in accordance with several example embodiments;

FIG. 5 illustrates a method for making an electronic component module in accordance with an example embodiment; and

FIG. 6 is a schematic illustration of an exemplary computing system.

Reference will now be made to the exemplary embodiments illustrated, and specific language will be used herein to describe the same. It will nevertheless be understood that no limitation of the scope or to specific invention embodiments is thereby intended.

### DESCRIPTION OF EMBODIMENTS

Before technology embodiments are disclosed and described, it is to be understood that no limitation to the particular structures, process steps, or materials disclosed herein is intended, but also includes equivalents thereof as would be recognized by those ordinarily skilled in the relevant arts. It should also be understood that terminology employed herein is used for the purpose of describing particular examples only and is not intended to be limiting. The same reference numerals in different drawings represent the same element. Numbers provided in flow charts and processes are provided for clarity in illustrating steps and operations and do not necessarily indicate a particular order or sequence. Unless defined otherwise, all technical and scientific terms used herein have the same meaning as commonly understood by one of ordinary skill in the art to which this disclosure belongs.

As used in this written description, the singular forms “a,” “an” and “the” provide express support for plural referents unless the context clearly dictates otherwise. Thus, for example, reference to “a layer” includes a plurality of such layers.

In this application, “comprises,” “comprising,” “containing” and “having” and the like can have the meaning ascribed to them in U.S. Patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. Patent law. “Consisting essentially of” or “consists essentially of” have the meaning generally ascribed to them by U.S. Patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the composition's nature or characteristics would be permissible if present under the “consisting essentially of” language, even though not expressly recited in a list of items following such terminology. When using an open ended term in the written description like “comprising” or “including,” it is understood that direct support should be afforded also to “consisting essentially of” language as well as “consisting of” language as if stated explicitly and vice versa.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein.

The term “coupled,” as used herein, is defined as directly or indirectly connected in an electrical or nonelectrical manner. “Directly coupled” items or objects are in physical contact and attached to one another. Objects described herein as being “adjacent to” each other may be in physical contact with each other, in close proximity to each other, or in the same general region or area as each other, as appropriate for the context in which the phrase is used.

Occurrences of the phrase “in one embodiment,” or “in one aspect,” herein do not necessarily all refer to the same embodiment or aspect.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, sizes, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

Reference throughout this specification to “an example” means that a particular feature, structure, or characteristic described in connection with the example is included in at least one embodiment. Thus, appearances of the phrases “in an example” in various places throughout this specification are not necessarily all referring to the same embodiment.

Furthermore, the described features, structures, or characteristics may be combined in any suitable manner in one or more embodiments. In this description, numerous specific details are provided, such as examples of layouts, distances, network examples, etc. One skilled in the relevant art will recognize, however, that many variations are possible without one or more of the specific details, or with other methods, components, layouts, measurements, etc. In other instances, well-known structures, materials, or operations are not shown or described in detail but are considered well within the scope of the disclosure.

### Example Embodiments

An initial overview of technology embodiments is provided below and specific technology embodiments are then described in further detail. This initial summary is intended to aid readers in understanding the technology more quickly but is not intended to identify key or essential features of the technology nor is it intended to limit the scope of the claimed subject matter.

Server packages with non-replaceable on-package memory cannot be easily upgraded with increased memory capabilities. As a result, an entire server package must be replaced in order to upgrade system memory, which is not cost-effective. Although server packages that utilize off-package memory do provide flexibility in configuring system memory, locating server package memory on the server motherboard may be problematic by raising space and thermal management issues on the motherboard. In addition, off-loading memory from the server package negates advantages provided by a self-contained server package that includes memory with a processor.

Accordingly, electronic device packages are disclosed that provides for on-package memory that is user replaceable to enable flexibility in system memory capabilities. In one example, an electronic device package in accordance with the present disclosure can comprise a package substrate. The electronic device package can also comprise a processor mounted on the package substrate. Additionally, the electronic device package can comprise a memory socket mounted on the package substrate and operably coupled to the processor. The memory socket can be operable to removably couple with a memory module or unit and facilitate electrical communication between the processor and the memory module or unit. A memory module can comprise a plurality of printed circuit boards (PCBs). Each PCB can have a bottom edge and a plurality of contact pads located about the bottom edge. Additionally, the memory module can comprise a memory device mounted on at least one of the plurality of PCBs and electrically connected to at least one of the pluralities of contact pads to facilitate electrically coupling the memory module with an external electronic component, such as a processor. Associated systems and methods are also disclosed.

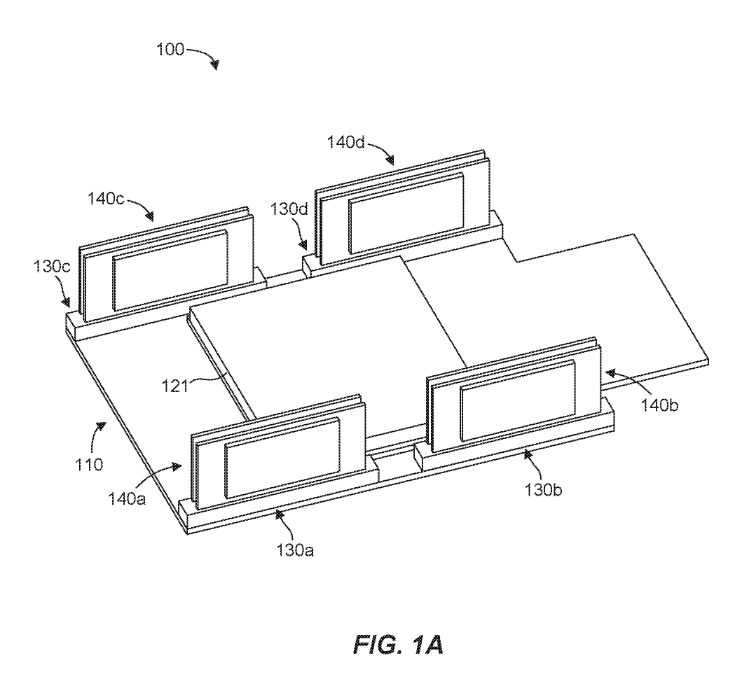

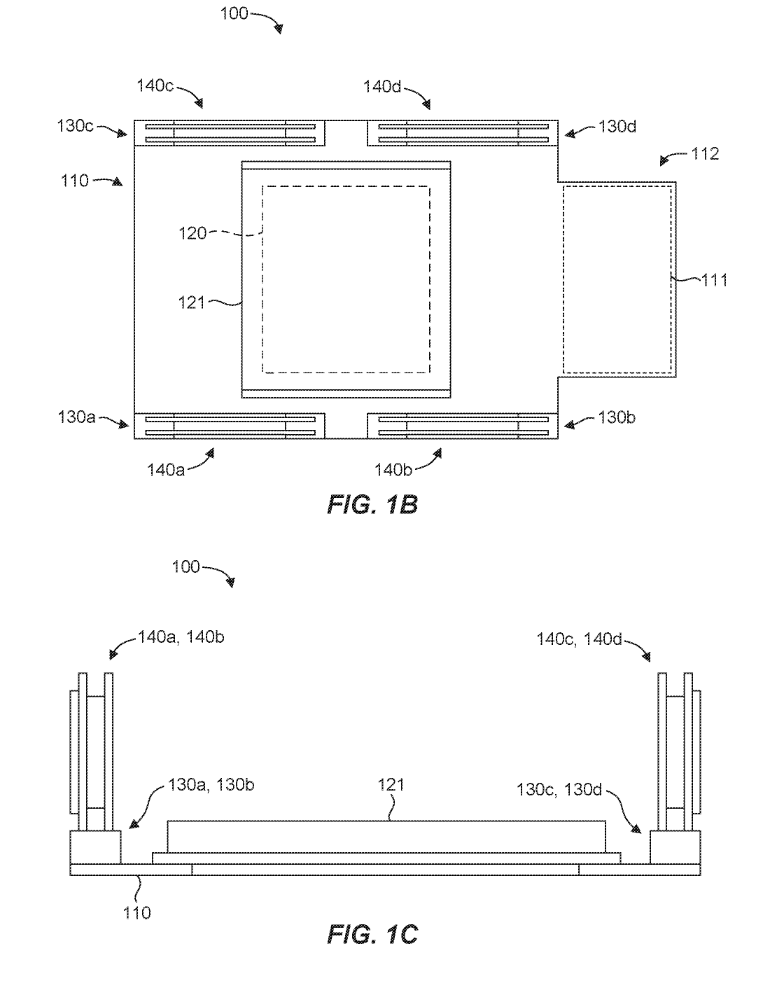

Referring to FIGS. 1A-1C, an exemplary electronic device package 100 is illustrated. FIG. 1A shows the package 100 in a perspective view, FIG. 1B shows the package 100 in a top view, and FIG. 1C shows the package 100 in an end view. The package 100 can include a package substrate 110. The package 100 can also include one or more electronic components 120 (FIG. 1B) mechanically and electrically coupled to (e.g., mounted on) the substrate 110. In the illustrated embodiment, the electronic component 120 is hidden from view by a heat spreader 121, which can be disposed at least partially about the electronic component 120.

The electronic component 120 can be any electronic device or component that may be included in an electronic device package, such as a semiconductor device (e.g., a die, a chip, a processor, computer memory, a platform controller hub, etc.). In one embodiment, some of the electronic components may represent a discrete chip, which may include an integrated circuit. The electronic components may be, include, or be a part of a processor (e.g., a CPU, a GPU, etc.), a computer memory device (e.g., ROM, SRAM, DRAM, flash memory, EEPROM, etc.), an application specific integrated circuit (ASIC), a platform controller hub (PCH), a field programmable gate array (FPGA), a modem, a system on a chip (SOC), a system in a package (SIP), or a package on a package (POP) in some embodiments. An electronic component can be any passive electronic device or component, such as a capacitor, resistor, etc. It should be recognized that any suitable number of electronic components can be included.

The package substrate 110 may be of any suitable construction or material. For example, the substrate 110 may include typical substrate materials. In some embodiments, the substrate 110 may be configured as an epoxy-based laminate substrate having a core and/or build-up layers. The substrate 110 may be configured as other suitable types of substrates in other embodiments. For example, the substrate can be formed primarily of any suitable semiconductor material (e.g., a silicon, gallium, indium, germanium, or variations or combinations thereof, among other substrates), one or more insulating layers, such as glass-reinforced epoxy, such as FR-4, polytetrafluoroethylene (Teflon), cotton-paper reinforced epoxy (CEM-3), phenolic-glass (G3), paper-phenolic (FR-1 or FR-2), polyester-glass (CEM-5), ABF (Ajinomoto Build-up Film), any other dielectric material, such as glass, or any combination thereof, such as can be used in printed circuit boards (PCBs). In some embodiments, the substrate 110 can be constructed primarily of silicon and/or may be configured as an interposer or a redistribution layer (RDL).

The electronic component 120 can be electrically coupled to the package substrate 110 according to a variety of suitable configurations including a flip-chip configuration, wire bonding, and the like. The electronic component 120 can be electrically coupled to the substrate 110 using interconnect structures (e.g., solder balls or bumps and/or wire bonds) configured to route electrical signals between the electronic component 120 and the substrate 110. In some embodiments, the interconnect structures may be configured to route electrical signals such as, for example, I/O signals and/or power or ground signals associated with the operation of the electronic components. In one aspect, multiple electronic components can be in a stacked relationship, for example, to save space and enable smaller form factors. It should be recognized that any suitable number of electronic components can be included in a stack. At least some of the stacked electronic components can be wirebond based or flip chip integrated circuits (e.g., ASIC, DRAM, and NAND). Such integrated circuits can be electrically coupled to one another by wirebond connections or solder bumps or solder balls.

The package substrate 110 may include electrically conductive elements or electrical routing features (not shown) configured to route electrical signals to or from electronic components. The electrical routing features may be internal (e.g., disposed at least partially within a thickness of the substrate 110) and/or external to the substrate 110. For example, in some embodiments, the substrate 110 may include electrical routing features such as pads, vias, and/or traces configured to receive the interconnect structures and route electrical signals to or from electronic components. The pads, vias, and traces can be constructed of the same or similar electrically conductive materials, or of different electrically conductive materials. Any suitable electrically conductive material can be utilized, such as copper, gold, etc. In some embodiments, the substrate 110 can include a solder resist material or other surface treatment forming an outer layer of the substrate. Interconnect structures, such as contact pads or solder balls, can be coupled to a suitable surface of the substrate 110 to facilitate electrically coupling the package 100 with an external electronic component, such as a next level component (e.g., a substrate or circuit board such as a motherboard) for power and/or signaling. In the illustrated embodiment, contact pads (identified generally at 111 in FIG. 1B) can be located in an interconnect region 112 of the substrate 110, which can be inserted into an interconnect socket (e.g., a slot) of a next level component.

In addition, the electronic device package 100 can include one or more interconnect sockets 130a-d and one or more electronic component modules 140a-d. The interconnect sockets 130a-d can be mounted on the package substrate 110 and operably coupled to the electronic component 120. The interconnect sockets 130a-d can be operable to removably couple with the electronic component modules 140a-d and facilitate electrical communication between the electronic component 120 and the modules 140a-d. For example, the interconnect sockets 130a-d can be configured to provide signals and/or power to electronic component modules 140a-d. It should be recognized that the package 100 can include any suitable number of interconnect sockets, which may include multiple interconnect sockets that can be the same or different from one another. In addition, the package 100 can include any suitable number of electronic component modules, may include multiple electronic component modules that can be the same or different from one another. In some embodiments, the number of interconnect sockets may exceed the number of electronic component modules. Electronic component modules can have different capabilities and attributes, which can enable flexibility in the configuration of the package 100.

The interconnect socket 130a-d can be mounted to the package substrate 110 in any suitable location of the electronic device package 100. In general, an interconnect socket can be located wherever there is available “real estate” on the package substrate 110 and that will accommodate the presence of an electronic component module 140a-d. For example, as shown in FIGS. 1A-1C, the interconnect sockets 130a-d can be located on a top side of the package substrate 110 and positioned laterally relative to the electronic component 120 and associated heat spreader 121, which may also be located on the top side of the substrate 110. In some embodiments, as shown in FIGS. 1A-1C, the interconnect sockets 130a-d can be proximate lateral sides of the package substrate 110 and thus be located “outboard” the electronic component 120. Such a configuration can facilitate effective thermal management of the electronic component 120 and the electronic component modules 140a-d. Thermal management of the electronic device package 100 can be designed to provide separate thermal solutions for the electronic component 120 and the electronic component modules 140a-d or to combine thermal solutions for the electronic component 120 and one or more of the electronic component modules 140a-d.

Each interconnect socket 130a-d can include two or more slot receptacles configured to receive and couple with a module 140a-d. This is illustrated in FIG. 2 for a representative interconnect socket 130 and a representative electronic component module 140. The slot receptacles 131a, 131b can be at least partially formed by a connector housing 136. Thus, multiple slot receptacles can be formed in a single connector housing. The connector housing 136 can be constructed of any suitable material, such as a polymer and/or a metal. In one aspect, slot receptacles 131a, 131b of the interconnect socket 130 can have contact terminals to electrically couple with the module 140. For example, the slot receptacle 131a can include contact terminals 132a, 133a, and the slot receptacle 131b can include contact terminals 132b, 133b. A contact terminal can be formed of any suitable conductive material, such as a metal (e.g., copper, gold, steel, etc.).

The interconnect socket 130 can be mounted to a package substrate in any suitable manner. For example, the interconnect socket 130 can include leads 134a, 135a, 134b, 135b configured as pins that extend from or are otherwise electrically coupled to the respective contact terminals 132a, 133a, 132b, 133b of the interconnect socket 130. The leads 134a, 135a, 134b, 135b and/or contact terminals 132a, 133a, 132b, 133b can be at least partially supported by the housing 136. The leads 134a, 135a, 134b, 135b can be configured to extend at least partially into one or more vias of a substrate and be electrically coupled to the vias by soldering. Thus, the interconnect socket 130 can be through-hole mounted to a package substrate. In one embodiment, the interconnect socket 130 can be surface mounted to a package substrate. For example, leads can be configured to contact one or more pads of a substrate and be electrically coupled to the pads by soldering. The interconnect socket 130 can therefore be mechanically and electrically coupled to (e.g., mounted on) a package substrate in any suitable manner.

With further reference to FIG. 2, the electronic component module 140 can include two or more module substrates 141a, 141b. The electronic component module 140 can also include one or more electronic components 150 mechanically and electrically coupled to (e.g., mounted on) at least one of the module substrates. In the illustrated embodiment, the electronic component 150 is directly mounted on and supported by the module substrate 141a. One or more electronic components 150 can be as described above with reference to the electronic component 120. Similarly, the module substrates 141a, 141b can be as described above with reference to the package substrate 110. Thus, a module substrate can include any suitable electrically conductive element or electrical routing feature and one or more electronic components can be mechanically and electrically coupled to a module substrate in any suitable manner and utilizing any suitable interconnect structure, such as surface mounting (e.g., a flip-chip configuration), wire bonding, through-hole mounting, etc. In the illustrated embodiment, the electronic component 150 is mounted on the module substrate 141a in a flip chip configuration, with solder bumps or solder balls 151 coupled to pads 142a on one side of the module substrate 141a.

In one aspect, the electronic component module 140 can include an interposer 160 to facilitate coupling the module substrates 141a, 141b to one another and/or facilitate coupling the electronic component 150 to one of the module substrates 141a, 141b. In the embodiment illustrated in FIG. 2, the interposer 160 is disposed between the module substrates 141a, 141b and operable to mechanically and electrically couple the module substrates 141a, 141b to one another. An interposer can have any suitable configuration or construction. In some respects, an interposer can utilize materials and be constructed in a manner similar to the package substrate 110 discussed above, for example, utilizing silicon material and interconnect structures such as pads, vias, and/or traces. Accordingly, an interposer can include any suitable electrically conductive element or electrical routing feature and can be mechanically and electrically coupled to a module substrate or electronic component in any suitable manner and utilizing any suitable interconnect structure, such as surface mounting, wire bonding, through-hole mounting, etc. In the illustrated embodiment, the interposer 160 can include pads 161, 162 on opposite sides of the interposer 160, which can be mechanically and electrically coupled to pads 143a, 142b of the respective module substrates 141a, 141b with solder bumps or solder balls 163, 164. The interposer 160 can include vias 165 electrically coupled to the pads 161, 162 on opposite sides of the interposer 160 to electrically couple the module substrates 141a, 141b. In the illustrated embodiment, the module substrates 141a, 141b are arranged in a side-by-side stack configuration with the interposer 160 disposed between the module substrates 141a, 141b.

The module substrates 141a, 141b can be configured to facilitate electrically coupling the module 140 with the interconnect socket 130. In one aspect, the module substrates 141a, 141b can include interconnect structures configured to interface with the contact terminals 132a, 133a and 132b, 133b of the respective slot receptacles 131a, 131b. For example, the module substrate 141a can include contact pads 144a, 145a (sometimes referred to as “pins”) located about a bottom edge 149a. The bottom edge 149a can be configured to be disposed (i.e., inserted) in the slot receptacle 131a, and the contact pads 144a, 145a can be configured to interface with the contact terminals 132a, 133a of the slot receptacle 131a. Similarly, the module substrate 141b can include contact pads 144b, 145b located about a bottom edge 149b. The bottom edge 149b can be configured to be disposed (i.e., inserted) in the slot receptacle 131b, and the contact pads 144b, 145b can be configured to interface with the contact terminals 132b, 133b of the slot receptacle 131b. The bottom edges 149a, 149b of the module substrates 141a, 141b can be oriented in the same direction to facilitate simultaneous insertion of the bottom edges 149a, 149b into the respective slot receptacles 131a, 131b. A contact pad can be formed of any suitable conductive material, such as a metal (e.g., copper, gold, steel, etc.).

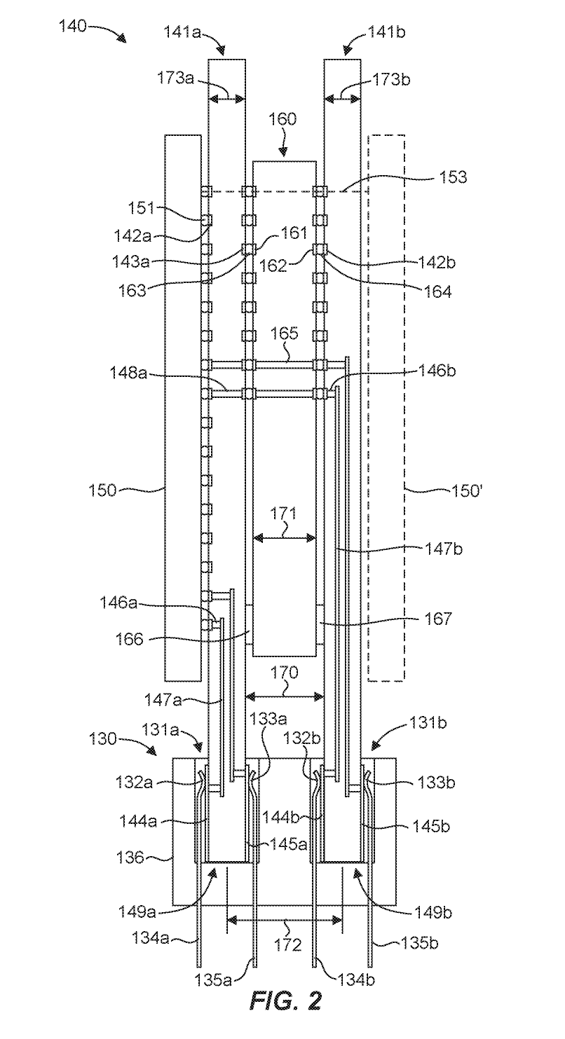

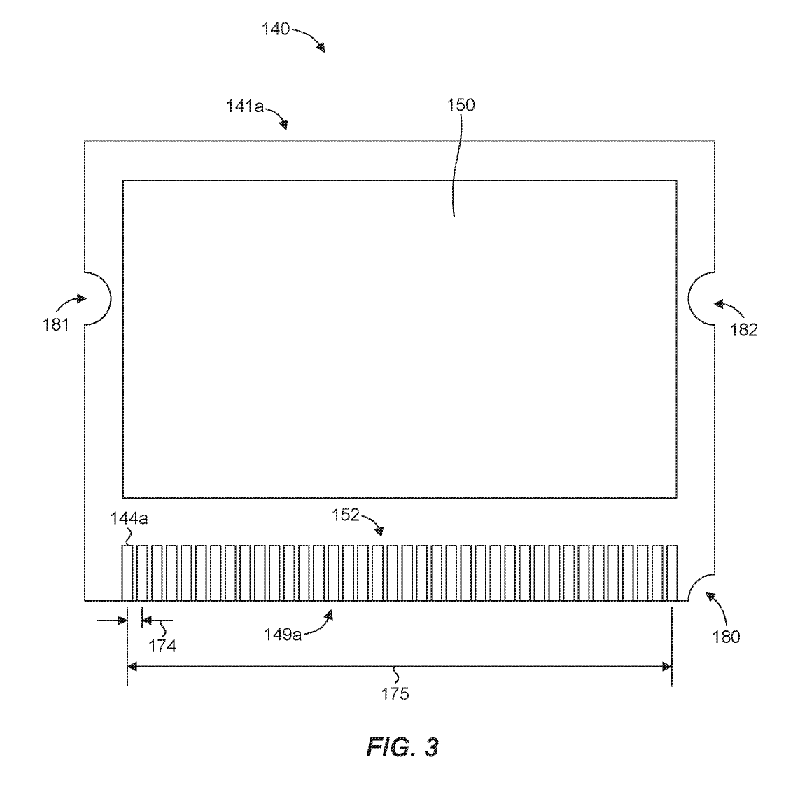

It should be recognized that a single module substrate can have any suitable number of contact pads, which may include more than one connector type or configuration, such as a protrusion, a receptacle, a pad, and/or any other suitable type of electrical contact for interfacing with an interconnect feature of an interconnect socket. In one aspect, multiple or groups of contact pads can be located on each side of the module substrates 141a, 141b. For example, FIG. 3 shows a group 152 of contact pads 144a located about the bottom edge 149a on an outer side of the module substrate 141a on which the electronic component 150 is mounted. In light of FIGS. 2 and 3, it should be recognized that a group of contact pads 145a can be located on an opposite, inner side of the module substrate 141a. In addition, a group of contact pads 144b can be located on an inner side of the module substrate 141b, and a group of contact pads 145b can be located on an opposite, outer side of the module substrate 141b.

With further reference to FIG. 2, the module substrates 141a, 141b can include electrically conductive elements or electrical routing features configured to electrically couple the electronic component 150 to the contact pads 144a, 145a and 144b, 145b. For example, interconnect structures and routing features such as pads 142a, vias 146a, and traces 147a of the module substrate 141a can be configured to facilitate electrically coupling the electronic component 150 to the contact pads 144a, 145a of the module substrate 141a. Interconnect structures and routing features such as pads 142a, 143a and vias 148a of the module substrate 141a can be configured to facilitate electrically coupling the electronic component 150 to the contact pads 144b, 145b of the module substrate 141b. In addition, interconnect structures and routing features such as pads 142b, vias 146b, and traces 147b of the module substrate 141b can be configured to facilitate electrically coupling the electronic component 150 to the contact pads 144b, 145b of the module substrate 141b. The vias 146a, 146b can be “blind” vias that terminate at the respective traces 147a, 147b. The via 148a can be a “through” via (e.g., a through silicon via (TSV)) that extends completely through a thickness of the module substrate 141a for communication with the interposer 160, which is sandwiched between the module substrates 141a, 141b. The via 165 of the interposer 160 can also be a “through” via that extends completely through a thickness of the interposer 160 for communication with the module substrate 141b. Thus, in the illustrated embodiment, the electronic device 150 can be electrically connected to all of the contact pads 144a, 145a and 144b, 145b of the respective module substrates 141a, 141b. In one aspect, different groups of contact pads (e.g., contact pads on opposite sides of a module substrate) can be electrically distinct from one another (e.g., as with dual inline memory module (DIMM) connectors).

In some embodiments, the electronic component module 140 can include multiple electronic components. For example, the electronic component module 140 can include electronic component 150′ in addition to the electronic component 150. In one example, the electronic component 150′ can be mounted on the module substrate 141b. In one aspect, two or more electronic components of an electronic component module can be electrically coupled to one another, as indicated at 153 in FIG. 2.

The module substrates 141a, 141b can be spaced apart from one another by any suitable distance 170. In some embodiments, the distance 170 can be from about 1 mm to about 4 mm. In the illustrated embodiments, the distance 170 can be established by a thickness 171 of the interposer 160 and by any thickness attributable to the interconnect structures coupling the interposer 160 and the module substrates 141a, 141b, such as the pads 143a, 161, 162, 142b and solder balls or bumps 163, 164.

In some embodiments, spacers 166, 167 can be included to provide additional mechanical stability for coupling the interposer 160 and one or more of the module substrates 141a, 141b. The spacers 166, 167 can be secured to the adjacent components in any suitable manner, such as with an adhesive. A thickness of the spacers 166, 167 can be configured to provide a desired distance 170 between the module substrates 141a, 141b. The spacers 166, 167 can be constructed of any suitable material, such as silicon, a polymer, a metal, etc. Any suitable number of spacers can be included in any suitable configuration.

The housing 136 can be configured to provide a center-to-center distance 172 between the slot receptacles 131a, 131b to facilitate coupling with the module substrates 141a, 141b. The distance 172 can be based on the distance 170 and thicknesses of the 173a, 173b of the respective module substrates 141a, 141b. Although it may be desirable to minimize the distances 170, 172, manufacturing and practical considerations for the electronic component module 140 and/or the interconnect socket 130 may dictate suitable distances 170, 172 that can be achieved. In some cases, the space occupied by the contact terminals 132a, 132b of the respective slot receptacles 131a, 131b and associated housing structure may dictate minimum distances 170, 172 that can be achieved.

Due to the nature of the mechanical connections between the interposer 160 and the module substrates 141a, 141b, manufacturing tolerances for these connections can impact the ability of the module substrates 141a, 141b to be inserted into the mating slot receptacles 131a, 131b and form effective electrical connections between the contact pads on the module substrates and the contact terminals in the slot receptacles. Suitable tolerances on the distance 170 can be up to about +/−0.25 mm. Suitable tolerances on the distance 172 can be up to about +/−0.25 mm.

Even with such tolerances, mating the module substrates 141a, 141b in the slot receptacles 131a, 131b may be difficult to achieve without some degree of mechanical interference that can cause stress in the interposer/module substrate connections that can lead to failure of the electronic component module 140. Accordingly, lower portions of the module substrates 141a, 141b extending from the interposer/module substrate connections can be configured to provide some flexibility or compliance that allows the lower portions of the module substrates 141a, 141b to bend or deflect in response to mechanical interference with the slot receptacles and therefore reduce stress that may be induced in the interposer/module substrate connections.

In one aspect, one or more of the module substrates 141a, 141b can include features to ensure proper coupling with the interconnect socket 130. Such features may be commonly found in DIMMs and mating sockets. For example, as shown in FIG. 3, the module substrate 141a can include a polarization notch 180 to ensure proper orientation and placement of the module substrates 141a, 141b in the slot receptacles 131a, 131b. A polarization key (not shown) can be included in the slot receptacle 131a. In some embodiments, locking features, such as locking notches 181, 182, can be included in one or more of the module substrates 141a, 141b to facilitate securing the electronic component module 140 to the interconnect socket 130 to prevent unwanted separation. A locking tab (not shown) can be coupled to the housing 136 and configured to interface with the locking notches 181, 182. In one aspect, one or more of the bottom edges 149a, 149b can be ramped, as known in the art, to reduce the required insertion force when coupling the electronic component module 140 with the interconnect socket 130.

In some embodiments, the electronic component 150 can be a computer memory device (e.g., ROM, SDRAM, DRAM, flash memory, EEPROM, etc.). Accordingly, the electronic component module 140 may be referred to as a memory module and the interconnect socket 130 may be referred to as a memory socket. In addition, the electronic component 120 may be, include, or be a part of a processor (e.g., a CPU, a GPU, etc.). In this case, the memory module may be utilized by the processor. In some embodiments, the package 100 can comprise a server package.

The present technology disclosed herein can enable replacement or customization of various electronic components of a package. For example, in the case of a server package, on-package memory can be replaced or expanded as desired to customize performance. Thus, the memory capabilities can be customized or upgraded without the need to replace the entire package, which includes one or more processors. Replaceable on-package memory can therefore provide system configuration flexibility with less expense.

In one aspect, interconnecting features of the electronic component module 140 and interconnect socket 130 can be configured similar to those commonly found in DIMMs and mating sockets. For example, as shown in FIG. 3, the contact pads 144a at the bottom edge 149a of the module 140 can be configured similar to the pads or pins of a DIMM. Therefore, the electronic component module 140 and interconnect socket 130 can be manufactured in accordance with current low cost, high volume PCB fabrication tolerances, surface mount, and signal routing capabilities. For example, a 0.4 mm pitch 174 between adjacent contact pads 144a over a contact length 175 of 30 mm can provide 76 contact pads 144a. Configuring the contact pads 145a, 144b, and 145b with the same pitch and contact length can provide a total of 304 contact pads for the electronic component module 140. This number of contact pads is roughly the amount of interconnect structures currently utilized by typical DDR4 memory technology but is provided in a smaller area. As a result, the present technology can increase interconnector (e.g., pin or pad) count density compared to typical DIMM connectors. Thus, the electronic component module 140 and socket 130 can provide a memory module and socket that can fit in a relatively small space, such as on a server package. In the embodiment illustrated in FIGS. 1A-1C, memory modules can be compact enough that four removable memory modules can fit on a single, space-constrained server package. In addition, by utilizing an edge connector and slot type interconnection, installation and serviceability is similar to board DIMMs that users are familiar with, and serviceability is improved when compared with on-package memories that are located under the CPU heat sink.

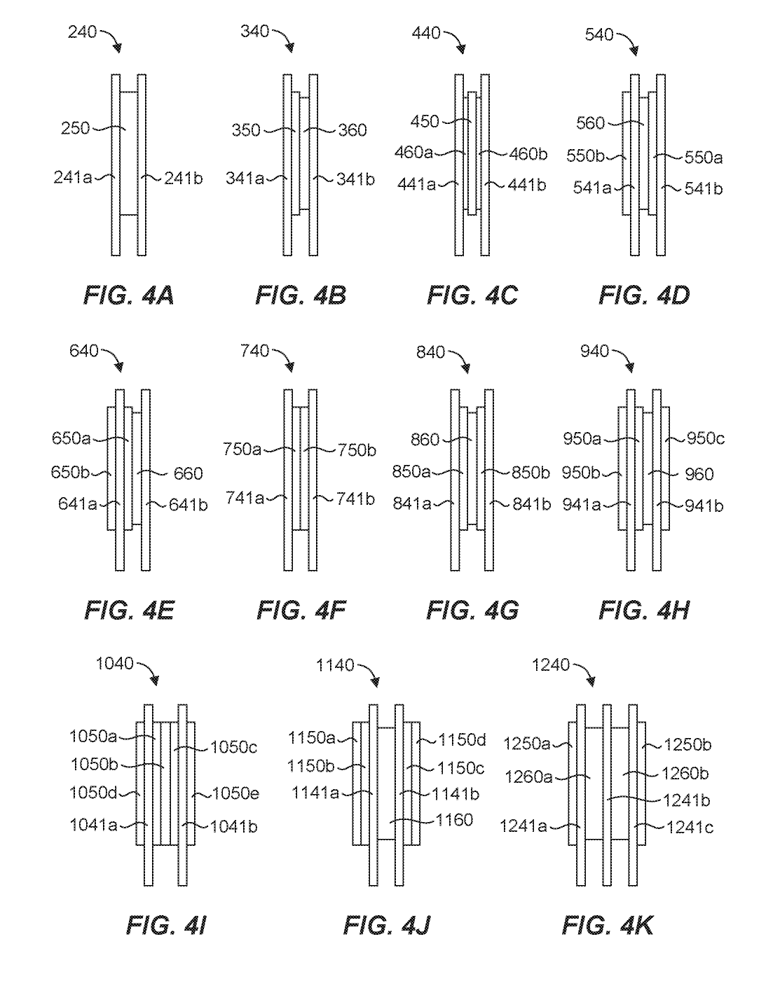

The configuration of the electronic component module 140 has two module substrates 141a, 141b separated by the interposer 160, with the electronic component 150 mounted directly on an outer side of the module substrate 141a. It should be recognized that any suitable configuration of module substrates, electronic components and, optionally, interposers can be utilized in an electronic component module in accordance with the present disclosure. Several examples of electronic component module configurations are illustrated in FIGS. 4A-4K. These configurations are not intended to be limiting in any way but, instead, illustrate the wide variety of ways that module substrates, electronic components and, optionally, interposers can be configured in accordance with the present technology. Specific configurations most suitable for a given application may depend on cooling solutions and signal routing considerations.

FIG. 4A shows an electronic component module 240. In this case, an electronic component 250 is disposed between two module substrates 241a, 241b, with no interposer. The electronic component 250 is directly mechanically and electrically coupled to the module substrates 241a, 241b and performs at least some of the same function as the interposer 160 of FIG. 2. The electronic component module 240 is one example of a module that includes only, or exactly, two module substrates.

FIG. 4B shows an electronic component module 340. In this case, an electronic component 350 and an interposer 360 are disposed between two module substrates 341a, 341b. The electronic component 350 is directly mechanically and electrically coupled to the interposer 360 and the module substrate 341a. The electronic component 350 is electrically coupled to the module substrate 341b through the interposer 360.

FIG. 4C shows an electronic component module 440. In this case, an electronic component 450 is disposed between two interposers 460a, 460b. The electronic component 450 and interposers 460a, 460b are between two module substrates 441a, 441b. The electronic component 450 is directly mechanically and electrically coupled to the interposers 460a, 460b. The electronic component 350 is electrically coupled to the module substrates 441a, 441b through the respective interposers 460a, 460b.

FIG. 4D shows an electronic component module 540. In this case, an electronic component 550a and an interposer 560 are disposed between two module substrates 541a, 541b, with an electronic component 550b disposed on an outer side of the module substrate 541a. The electronic component 550b and the interposer 560 are disposed on opposite sides of the same module substrate 541a. The electronic component 550a is directly mechanically and electrically coupled to the interposer 560 and the module substrate 541b. The electronic component 550a can be electrically coupled to the module substrate 541a through the interposer 560. The electronic component 550b is directly mechanically and electrically coupled to the module substrate 541a. The electronic component 550b can be electrically coupled to the module substrate 541b through the module substrate 541a, the interposer 560, and the electronic component 550a. The electronic components 550a, 550b are in direct contact with, and mounted on, different module substrates but can be in electrical communication with one another as facilitated by the interposer 560.

FIG. 4E shows an electronic component module 640. In this case, an electronic component 650a and an interposer 660 are disposed between two module substrates 641a, 641b, with an electronic component 650b disposed on an outer side of the module substrate 641a. The electronic component 650a is directly mechanically and electrically coupled to the module substrate 641a and the interposer 660. The electronic component 650a can be electrically coupled to the module substrate 641b through the interposer 660. The electronic component 650b is directly mechanically and electrically coupled to the module substrate 641a. The electronic component 650b can be electrically coupled to the module substrate 641b through the module substrate 641a, the electronic component 650a and the interposer 660. The electronic components 650a, 650b are in direct contact with, and mounted on, opposite sides of the same module substrate 641a and can be in electrical communication with one another.

FIG. 4F shows an electronic component module 740. In this case, two electronic components 750a, 750b are arranged in a stack configuration and disposed between two module substrates 741a, 741b, without an interposer. Although two electronic components are illustrated in a stack, it should be recognized that any suitable number of electronic components can be included in a stack. The electronic component 750a is directly mechanically and electrically coupled to the electronic component 750b and the module substrate 741a. The electronic component 750b is directly mechanically and electrically coupled to the electronic component 750a and the module substrate 741b. The electronic component 750a can be electrically coupled to the module substrate 741b through the electronic component 750b. The electronic component 750b can be electrically coupled to the module substrate 741a through the electronic component 750a. The electronic components 750a, 750b can be in electrical communication with one another.

FIG. 4G shows an electronic component module 840. In this case, an interposer 860 is disposed between two electronic components 850a, 850b. The electronic components 850a, 850b and interposer 860 are between two module substrates 841a, 841b. The electronic component 850a is directly mechanically and electrically coupled to the module substrate 841a and the interposer 860. The electronic component 850b is directly mechanically and electrically coupled to the module substrate 841b and the interposer 860. The electronic component 850a can be electrically coupled to the module substrate 841b through the interposer 860 and the electronic component 850b. The electronic component 850b can be electrically coupled to the module substrate 841a through the interposer 860 and the electronic component 850a. The electronic components 850a, 850b can be in electrical communication with one another.

FIG. 4H shows an electronic component module 940. In this case, an electronic component 950a and an interposer 960 are disposed between two module substrates 941a, 941b, with an electronic component 950b disposed on an outer side of the module substrate 941a and an electronic component 950c disposed on an outer side of the module substrate 941b. The electronic component 950a is directly mechanically and electrically coupled to the module substrate 941a and the interposer 960. The electronic component 950a can be electrically coupled to the module substrate 941b through the interposer 960. The electronic component 950b is directly mechanically and electrically coupled to the module substrate 941a. The electronic component 950b can be electrically coupled to the module substrate 941b through the module substrate 941a, the electronic component 950a, and the interposer 960. The electronic component 950c is directly mechanically and electrically coupled to the module substrate 941b. The electronic component 950c can be electrically coupled to the module substrate 941a through the module substrate 941b, the interposer 960, and the electronic component 950a. The electronic components 950a, 950b are in direct contact with opposite sides of the same module substrate 941a. Any of the electronic components 950a-c can be in electrical communication with one another through the module substrates 941a, 941b, the electronic component 950a, and/or the interposer 960, as applicable.

FIG. 4I shows an electronic component module 1040. In this case, electronic components 1050a-c are arranged in a stack configuration and disposed between two module substrates 1041a, 1041b, without an interposer, with an electronic component 1050d disposed on an outer side of the module substrate 1041a and an electronic component 1050e disposed on an outer side of the module substrate 1041b. The electronic components 1050a-c in a stack can be mechanically and electrically coupled to one another. The electronic component 1050a is directly mechanically and electrically coupled to the electronic component 1050b and the module substrate 1041a. The electronic component 1050c is directly mechanically and electrically coupled to the electronic component 1050a and the module substrate 1041b. The electronic component 1050d is directly mechanically and electrically coupled to the module substrate 1041a. The electronic component 1050e can be electrically coupled to the module substrate 1041b through the module substrate 1041a and the stack of electronic components 1050a-c. The electronic component 1050e is directly mechanically and electrically coupled to the module substrate 1041b. The electronic component 1050e can be electrically coupled to the module substrate 1041a through the module substrate 1041b and the stack of electronic components 1050a-c. The electronic components 1050a, 1050d are in direct contact with opposite sides of the same module substrate 1041a. The electronic components 1050c, 1050e are in direct contact with opposite sides of the same module substrate 1041b. Any of the electronic components 1050a-e can be in electrical communication with one another through the module substrates 1041a, 1041b and/or any of the electronic components 1050a-c, as applicable.

FIG. 4J shows an electronic component module 1140. In this case, an interposer 1160 is between or forming a bridge connecting two module substrates 1141a, 1141b, with a stack of multiple electronic components 1150a-b disposed on an outer side of the module substrate 1141a and a stack of multiple electronic components 1150c-d disposed on an outer side of the module substrate 1141b. The electronic components 1150a-b in a stack can be mechanically and electrically coupled to one another. Any of the electronic components 1150a-b in a stack can be electrically coupled to the module substrate 1141b through the module substrate 1141a and the interposer 1160. The electronic components 1150c-d in a stack can be mechanically and electrically coupled to one another. Any of the electronic components 1150c-d in a stack can be electrically coupled to the module substrate 1141a through the module substrate 1141b and the interposer 1160. Any of the electronic components 1150a-d can be in electrical communication with one another through the module substrates 1141a, 1141b, the interposer 1160, the electronic component 1050b, and/or the electronic component 1050c, as applicable.

FIG. 4K shows an electronic component module 1240. In this case, the electronic component module 1240 includes three or more module substrates 1241a-c. An interposer 1260a is between module substrates 1241a, 1241b, and an interposer 1260b is between module substrates 1241b, 1241c. An electronic component 1250a is disposed on an outer side of an outermost module substrate 1241a and an electronic component 1250b is disposed on an outer side of an outermost module substrate 1241c. The electronic components 1250a, 1250b are directly mounted on different module substrates but can be electrically coupled to one another or any of the module substrates 1241a-c through the module substrates 1241a-c and/or the interposers 1260a, 1260b, as applicable. Additional module substrates can be utilized as desired to fit an electronic component module within a given space and/or achieve a desired interconnect density. Any number of module substrates can be included in a stack of module substrates, limited only by practical considerations, such as tolerances, heat dissipation, etc.

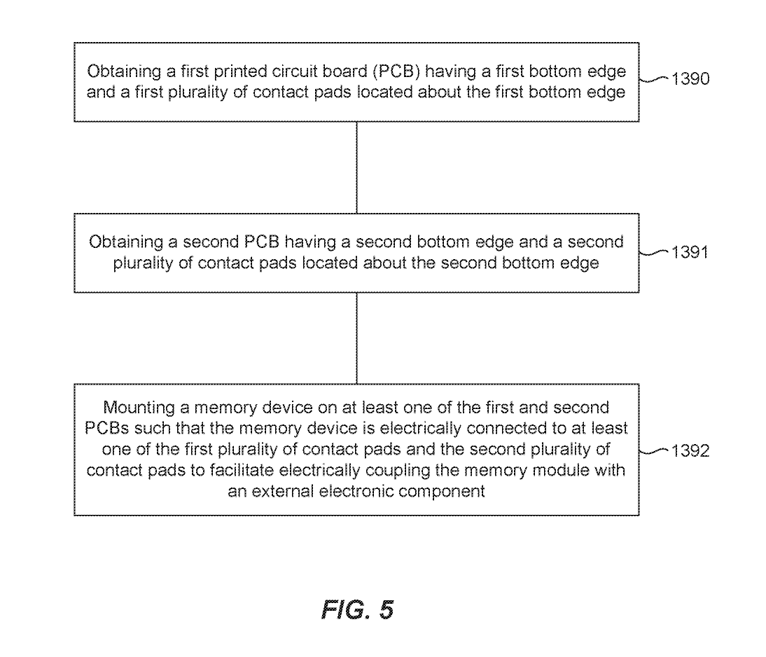

FIG. 5 illustrate aspects of exemplary methods or processes for making an electronic component module, such as the electronic component module 140. In one aspect, the method can be utilized to make a memory module. The method can comprise obtaining a first printed circuit board (PCB) having a first bottom edge and a first plurality of contact pads located about the first bottom edge 1390. The method can also comprise obtaining a second PCB having a second bottom edge and a second plurality of contact pads located about the second bottom edge 1391. Additionally, the method can comprise mounting a memory device on at least one of the first and second PCBs such that the memory device is electrically connected to at least one of the first plurality of contact pads and the second plurality of contact pads to facilitate electrically coupling the memory module with an external electronic component 1392. In one aspect, the method can comprise disposing an interposer between the first PCB and the second PCB. It is noted that no specific order is required in this method, though generally in one embodiment, these method steps can be carried out sequentially.

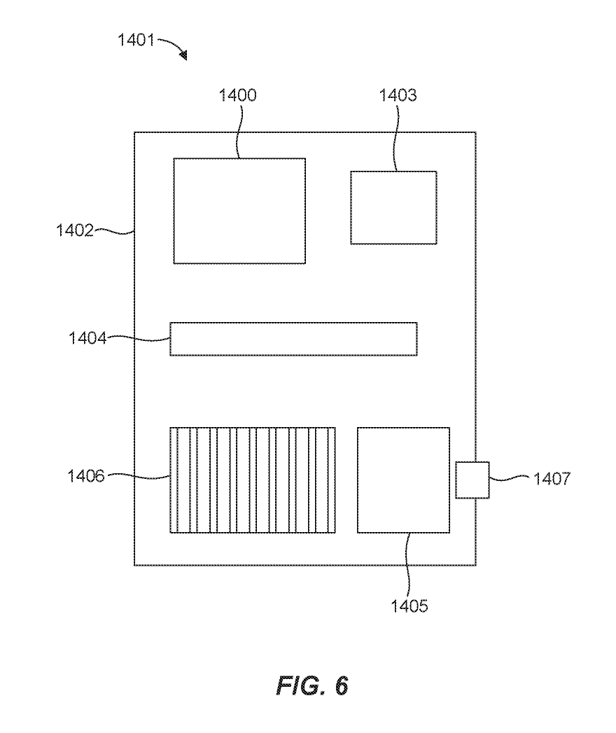

FIG. 6 schematically illustrates an example computing system 1401. The computing system 1401 can include an electronic device package 1400 as disclosed herein, operably coupled to a motherboard 1402. In one aspect, the computing system 1401 can also include a processor 1403, a memory device 1404, a radio 1405, a cooling system (e.g., a heat sink and/or a heat spreader) 1406, a port 1407, a slot, or any other suitable device or component, which can be operably coupled to the motherboard 1402. The computing system 1401 can comprise any type of computing system, such as a desktop computer, a laptop computer, a tablet computer, a smartphone, a server, a wearable electronic device, etc. Other embodiments need not include all of the features specified in FIG. 6, and may include alternative features not specified in FIG. 6.

### Examples

The following examples pertain to further embodiments.

In one example, there is provided a memory module comprising a plurality of printed circuit boards (PCBs), each having a bottom edge and a plurality of contact pads located about the bottom edge, and a memory device mounted on at least one of the plurality of PCBs and electrically connected to at least one of the pluralities of contact pads to facilitate electrically coupling the memory module with an external electronic component.

In one example of an electronic device package, the memory device is disposed between two of the plurality of PCBs.

In one example of an electronic device package, the memory device is electrically and mechanically coupled to the two of the plurality of PCBs.

In one example of an electronic device package, the memory device is mounted to the at least one of the plurality of PCBs by surface mounting, wire-bonding, through-hole mounting, or a combination thereof.

In one example, an electronic device package comprises an interposer disposed between two of the plurality of PCBs.

In one example of an electronic device package, the interposer is electrically and mechanically coupled to the two of the plurality of PCBs.

In one example of an electronic device package, the interposer is electrically and mechanically coupled to the two of the plurality of PCBs by surface mounting, wire-bonding, through-hole mounting, or a combination thereof.

In one example of an electronic device package, the memory device is disposed between two of the plurality of PCBs.

In one example of an electronic device package, the memory device and the interposer are disposed on opposite sides of a same one of the plurality of PCBs.

In one example of an electronic device package, the memory device is directly mounted to the two of the plurality of PCBs.

In one example of an electronic device package, the memory device is disposed on an outermost one of the plurality of PCBs.

In one example of an electronic device package, the memory device is disposed on an outer side of the outermost one of the plurality of PCBs.

In one example of an electronic device package, the memory device is electrically connected to all of the pluralities of contact pads.

In one example of an electronic device package, the plurality of PCBs are arranged in a side-by-side stack configuration.

In one example of an electronic device package, the bottom edges of the plurality of PCBs are oriented in a same direction.

In one example of an electronic device package, the memory device comprises a plurality of memory devices.

In one example of an electronic device package, two of the plurality of memory devices are mounted on two different PCBs.

In one example of an electronic device package, the two different PCBs are outermost of the plurality of PCBs.

In one example of an electronic device package, the two memory devices are disposed on outer sides of the two outermost of the plurality of PCBs.

In one example of an electronic device package, the plurality of PCBs comprises only the two outermost PCBs.

In one example, an electronic device package comprises an interposer disposed between the two PCBs.

In one example of an electronic device package, two of the plurality of memory devices are mounted on a same PCB.

In one example of an electronic device package, the two of the plurality of memory devices are mounted on opposite sides of the same PCB.

In one example of an electronic device package, two of the plurality of memory devices are arranged in a stack configuration.

In one example of an electronic device package, two of the plurality of memory devices are electrically coupled to one another.

In one example of an electronic device package, the plurality of PCBs comprises exactly two PCBs.

In one example of an electronic device package, the plurality of PCBs comprises three or more PCBs.

In one example of an electronic device package, the memory device comprises DRAM, SDRAM, or a combination thereof.

In one example of an electronic device package, the plurality of contact pads comprises a first group of contact pads on one side of the PCB and a second group of contact pads on an opposite side of the PCB.

In one example of an electronic device package, the first group of contact pads and the second group of contact pads are electrically distinct from one another.

In one example of an electronic device package, two of the plurality of PCBs are spaced apart by a distance of from about 1 mm to about 4 mm.

In one example, there is provided an electronic device package comprising a package substrate, a processor mounted on the package substrate, and a memory socket mounted on the package substrate and operably coupled to the processor, the memory socket being operable to removably couple with a memory module and facilitate electrical communication between the processor and the memory module.

In one example of an electronic device package, the memory socket comprises a plurality of memory sockets.

In one example of an electronic device package, the package comprises a server package.

In one example, an electronic device package comprises a heat spreader disposed at least partially about the processor.

In one example of an electronic device package, the memory socket comprises a slot receptacle configured to receive and couple with the memory module.

In one example of an electronic device package, the slot comprises a plurality of slots, each slot having a plurality of contact terminals.

In one example, an electronic device package comprises the memory module.

In one example of an electronic device package, the memory module comprises a plurality of printed circuit boards (PCBs), each having a bottom edge and a plurality of contact pads located about the bottom edge, wherein the bottom edge is configured to be disposed in one of the plurality of slots and the plurality of contact pads is configured to interface with the plurality of contact terminals, and a memory device mounted on at least one of the plurality of PCBs and electrically connected to at least one of the pluralities of contact pads to facilitate electrically coupling the memory module with the processor.

In one example of an electronic device package, the memory device is disposed between two of the plurality of PCBs.

In one example of an electronic device package, the memory device is electrically and mechanically coupled to the two of the plurality of PCBs.

In one example of an electronic device package, the memory device is mounted to the at least one of the plurality of PCBs by surface mounting, wire-bonding, through-hole mounting, or a combination thereof.

In one example, an electronic device package comprises an interposer disposed between two of the plurality of PCBs.

In one example of an electronic device package, the interposer is electrically and mechanically coupled to the two of the plurality of PCBs.

In one example of an electronic device package, the interposer is electrically and mechanically coupled to the two of the plurality of PCBs by surface mounting, wire-bonding, through-hole mounting, or a combination thereof.

In one example of an electronic device package, the memory device is disposed between two of the plurality of PCBs.

In one example of an electronic device package, the memory device and the interposer are disposed on opposite sides of a same one of the plurality of PCBs.

In one example of an electronic device package, the memory device is directly mounted to the two of the plurality of PCBs.

In one example of an electronic device package, the memory device is disposed on an outermost one of the plurality of PCBs.

In one example of an electronic device package, the memory device is disposed on an outer side of the outermost one of the plurality of PCBs.

In one example of an electronic device package, the memory device is electrically connected to all of the pluralities of contact pads.

In one example of an electronic device package, the plurality of PCBs are arranged in a side-by-side stack configuration.

In one example of an electronic device package, the bottom edges of the plurality of PCBs are oriented in a same direction.

In one example of an electronic device package, the memory device comprises a plurality of memory devices.

In one example of an electronic device package, two of the plurality of memory devices are mounted on two different PCBs.

In one example of an electronic device package, the two different PCBs are outermost of the plurality of PCBs.

In one example of an electronic device package, the two memory devices are disposed on outer sides of the two outermost of the plurality of PCBs.

In one example of an electronic device package, the plurality of PCBs comprises only the two outermost PCBs.

In one example, an electronic device package comprises an interposer disposed between the two PCBs.

In one example of an electronic device package, two of the plurality of memory devices are mounted on a same PCB.

In one example of an electronic device package, the two of the plurality of memory devices are mounted on opposite sides of the same PCB.

In one example of an electronic device package, two of the plurality of memory devices are arranged in a stack configuration.

In one example of an electronic device package, two of the plurality of memory devices are electrically coupled to one another.

In one example of an electronic device package, the plurality of PCBs comprises exactly two PCBs.

In one example of an electronic device package, the plurality of PCBs comprises three or more PCBs.

In one example of an electronic device package, the memory device comprises DRAM, SDRAM, or a combination thereof.

In one example of an electronic device package, the plurality of contact pads comprises a first group of contact pads on one side of the PCB and a second group of contact pads on an opposite side of the PCB.

In one example of an electronic device package, the first group of contact pads and the second group of contact pads are electrically distinct from one another.

In one example of an electronic device package, two of the plurality of PCBs are spaced apart by a distance of from about 1 mm to about 4 mm.

In one example, there is provided a computing system comprising a motherboard and an electronic device package operably coupled to the motherboard, the electronic device package comprising a package substrate, a processor mounted on the package substrate, and a memory socket mounted on the package substrate and operably coupled to the processor, the memory socket being operable to removably couple with a memory module and facilitate electrical communication between the processor and the memory module.

In one example of a computing system, the computing system comprises a desktop computer, a laptop, a tablet, a smartphone, a server, a wearable electronic device, or a combination thereof.

In one example of a computing system, the computing system further comprises a processor, a memory device, a cooling system, a radio, a slot, a port, or a combination thereof operably coupled to the motherboard.

In one example, there is provided a method for making a memory module comprising obtaining a first printed circuit board (PCB) having a first bottom edge and a first plurality of contact pads located about the first bottom edge, obtaining a second PCB having a second bottom edge and a second plurality of contact pads located about the second bottom edge, and mounting a memory device on at least one of the first and second PCBs such that the memory device is electrically connected to at least one of the first plurality of contact pads and the second plurality of contact pads to facilitate electrically coupling the memory module with an external electronic component.

In one example of a method for making an electronic device package, the memory device is disposed between the first PCB and the second PCB.

In one example of a method for making an electronic device package, the memory device is electrically and mechanically coupled to the first PCB and the second PCB.

In one example of a method for making an electronic device package, the memory device is mounted to the at least one of the first PCB and the second PCB by surface mounting, wire-bonding, through-hole mounting, or a combination thereof.

In one example, a method for making an electronic device package comprises disposing an interposer between the first PCB and the second PCB.

In one example of a method for making an electronic device package, the interposer is electrically and mechanically coupled to the first PCB and the second PCB.

In one example of a method for making an electronic device package, the interposer is electrically and mechanically coupled to the first PCB and the second PCB by surface mounting, wire-bonding, through-hole mounting, or a combination thereof.

In one example of a method for making an electronic device package, the memory device is disposed between the first PCB and the second PCB.

In one example of a method for making an electronic device package, the memory device and the interposer are disposed on opposite sides of the first PCB or the second PCB.

In one example of a method for making an electronic device package, the memory device is directly mounted to the first PCB and the second PCB.

In one example of a method for making an electronic device package, the memory device is disposed on an outer side of the first PCB or the second PCB.

In one example of a method for making an electronic device package, the memory device is electrically connected to the first plurality of contact pads and the second plurality of contact pads.

In one example of a method for making an electronic device package, the first PCB and the second PCB are arranged in a side-by-side stack configuration.

In one example of a method for making an electronic device package, the first bottom edge and the second bottom edge are oriented in a same direction.

In one example of a method for making an electronic device package, the memory device comprises a plurality of memory devices.

In one example of a method for making an electronic device package, one of the plurality of memory devices is mounted on the first PCB and another of the plurality of memory devices is mounted on the second PCB.

In one example of a method for making an electronic device package, the two memory devices are disposed on outer sides of the first PCB and the second PCB.

In one example, a method for making an electronic device package comprises disposing an interposer between the first PCB and the second PCB.

In one example of a method for making an electronic device package, two of the plurality of memory devices are mounted on the first PCB or the second PCB.

In one example of a method for making an electronic device package, the two of the plurality of memory devices are mounted on opposite sides of the first PCB or the second PCB.

In one example of a method for making an electronic device package, two of the plurality of memory devices are arranged in a stack configuration.

In one example of a method for making an electronic device package, two of the plurality of memory devices are electrically coupled to one another.

In one example of a method for making an electronic device package, the memory device comprises DRAM, SDRAM, or a combination thereof.

In one example of a method for making an electronic device package, the first plurality of contact pads comprises a first group of contact pads on one side of the first PCB and a second group of contact pads on an opposite side of the first PCB.

In one example of a method for making an electronic device package, the first group of contact pads and the second group of contact pads are electrically distinct from one another.

In one example of a method for making an electronic device package, first PCB and the second PCB are spaced apart by a distance of from about 1 mm to about 4 mm.

Circuitry used in electronic components or devices (e.g. a die) of an electronic device package can include hardware, firmware, program code, executable code, computer instructions, and/or software. Electronic components and devices can include a non-transitory computer readable storage medium which can be a computer readable storage medium that does not include signal. In the case of program code execution on programmable computers, the computing devices recited herein may include a processor, a storage medium readable by the processor (including volatile and non-volatile memory and/or storage elements), at least one input device, and at least one output device. Volatile and non-volatile memory and/or storage elements may be a RAM, EPROM, flash drive, optical drive, magnetic hard drive, solid state drive, or other medium for storing electronic data. Node and wireless devices may also include a transceiver module, a counter module, a processing module, and/or a clock module or timer module. One or more programs that may implement or utilize any techniques described herein may use an application programming interface (API), reusable controls, and the like. Such programs may be implemented in a high level procedural or object oriented programming language to communicate with a computer system. However, the program(s) may be implemented in assembly or machine language, if desired. In any case, the language may be a compiled or interpreted language, and combined with hardware implementations.

While the forgoing examples are illustrative of the specific embodiments in one or more particular applications, it will be apparent to those of ordinary skill in the art that numerous modifications in form, usage and details of implementation can be made without departing from the principles and concepts articulated herein.

1. A memory module, comprising:
a plurality of module substrates, each having a bottom edge and a plurality of contact pads located about the bottom edge; and
a memory device mounted on at least one of the plurality of module substrates and electrically connected to at least one of the pluralities of contact pads to facilitate electrically coupling the memory module with an external electronic component, wherein the memory device is disposed between two of the plurality of module substrates.

2. (canceled)

3. The memory module of claim 1 wherein the memory device is electrically and mechanically coupled to the two of the plurality of module substrates.

4. The memory module of claim 1, further comprising an interposer disposed between two of the plurality of module substrates.

5. The memory module of claim 4, wherein the interposer is electrically and mechanically coupled to the two of the plurality of module substrates.

6. The memory module of claim 4, wherein the memory device is disposed between two of the plurality of PCBs.

7. The memory module of claim 4, wherein the memory device and the interposer are disposed on opposite sides of a same one of the plurality of PCBs.

8. The memory module of claim 4, wherein the memory device is directly mounted to the two of the plurality of PCBs.

9. The memory module of claim 1, wherein the memory device is disposed on an outermost one of the plurality of PCBs.

10. The memory module of claim 9, wherein the memory device is disposed on an outer side of the outermost one of the plurality of PCBs.

11. The memory module of claim 1, wherein the memory device is electrically connected to all of the pluralities of contact pads.

12. The memory module of claim 1, wherein the plurality of PCBs are arranged in a side-by-side stack configuration.

13. The memory module of claim 1, wherein the bottom edges of the plurality of PCBs are oriented in a same direction.

14. The memory module of claim 1, wherein the memory device comprises a plurality of memory devices.

15. The memory module of claim 14, wherein two of the plurality of memory devices are mounted on two different PCBs.

16. The memory module of claim 1, wherein the plurality of PCBs comprises exactly two PCBs.

17. The memory module of claim 1, wherein the plurality of PCBs comprises three or more PCBs.

18. The memory module of claim 1, wherein the plurality of contact pads comprises a first group of contact pads on one side of the PCB and a second group of contact pads on an opposite side of the PCB.

19. The memory module of claim 18, wherein the first group of contact pads and the second group of contact pads are electrically distinct from one another.

20. The memory module of claim 1, wherein two of the plurality of PCBs are spaced apart by a distance of from about 1 mm to about 4 mm.

21. An electronic device package, comprising:
a package substrate;
a processor mounted on the package substrate; and
a memory socket mounted on the package substrate and operably coupled to the processor, the memory socket being operable to removably couple with a memory module and facilitate electrical communication between the processor and the memory module.

22. The electronic device package of claim 21, wherein the memory socket comprises a plurality of memory sockets.

23. The electronic device package of claim 21, wherein the package comprises a server package.

24. The electronic device package of claim 21, further comprising a heat spreader disposed at least partially about the processor.

25. The electronic device package of claim 21, wherein the memory socket comprises a slot receptacle configured to receive and couple with the memory module.

26. The electronic device package of claim 25, wherein the slot comprises a plurality of slots, each slot having a plurality of contact terminals.

27. The electronic device package of claim 26, further comprising the memory module.

28. The memory module of claim 1, wherein the memory device is mounted on a side of at least one of the plurality of module substrates that is not opposite the bottom edge.

29. The memory module of claim 1, wherein at least two of the plurality of module substrates are positioned in a parallel orientation.
